(19) United States
(12) Patent Application Publication
(10) Pub. No.: US 2016/0130694 A1
(43) Pub. Date: May 12, 2016

(54) TIN/TIC COATING AND METHOD FOR MANUFACTURING THE TIN/TIC COATING AND ARTICLES SO COATED

(71) Applicants: HONG FU JIN PRECISION INDUSTRY (Shenzhen) CO., LTD, Shenzhen (CN); HON HAI PRECISION INDUSTRY CO., LTD., New Taipei (TW)

(72) Inventors: JUN-FEI FANG, Shenzhen (CN); WEN-BAO WANG, Shenzhen (CN)

(21) Appl. No.: 14/589,815

(22) Filed: Jan. 5, 2015

(30) Foreign Application Priority Data
Nov. 11, 2014 (CN) 201410630829.X

(51) Int. Cl. C23C 14/34; C23C 14/06

(52) U.S. Cl. CPC C23C 14/3464; C23C 14/3492; C23C 14/0635; C23C 14/0641

(57) ABSTRACT

An article includes a substrate, a Ti-bottom layer deposited on the substrate and a TiN/TiC coating deposited on the Ti-bottom layer. The TiN/TiC coating includes a plurality of TiN-nano layers and a plurality of TiC-nano layers. Each TiN-nano layer and each TiC-nano layers are alternately deposited on the Ti-bottom layer. The TiN/TiC coating has good toughness and high hardness. A method for manufacturing the TiN/TiC coating is also provided.

### FIELD

The subject matter herein generally relates to protective coatings.

### BACKGROUND

Tools are provided with wear resistance against friction, erosion, or mechanical loadings during manufacturing or other operations by having a hard coating of TiN, TiCN, TiAlN, or the like, on a base of high speed steel, cemented carbide, cermet, or the like. In particular, TiAlN has been a favored choice in the case of the coating formed on a high speed or hardened steel tool. The hardness of the material to be cut or ground by the tool and increases in the processing speed require an improved wear resistance.

### BRIEF DESCRIPTION OF THE DRAWINGS

Implementations of the present technology will now be described, by way of example only, with reference to the attached figures.

FIG. 1 is a cross-sectional view of an embodiment of an article coated with a TiN/TiC coating.

FIG. 2 is an X-ray diffraction pattern of the article coated with the TiN/TiC coating.

FIG. 3 is a diagram showing test results of the nano-hardness of the TiN/TiC coating.

FIG. 4 is a flow chart of a process for a method for manufacturing the TiN/TiC coating.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The term “comprising” when utilized, means “including, but not necessarily limited to”; it specifically indicates open-ended inclusion or membership in the so-described combination, group, series and the like.

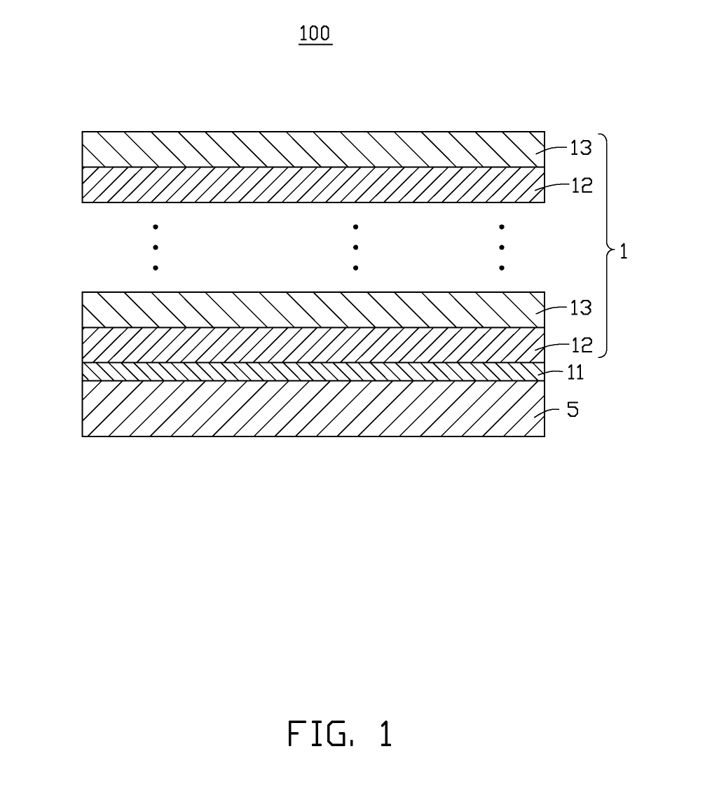

FIG. 1 illustrates an embodiment of an article 100. The article 100 can be a cutting tool, a precision measuring tool, a mold, or other tools. The article 100 can include a substrate 5, a Ti-bottom layer 11 deposited on the substrate 5 and a TiN/TiC coating 1 deposited on the Ti-bottom layer 11. The substrate 5 can be a high hardness material, such as high speed steel, cemented carbide, cermet, ceramic, and sintered diamond. In the illustrated embodiment, the substrate 5 can be wolfram carbide (WC). The Ti-bottom layer 11 can improve adhesiveness of the TiN/TiC coating 1 attached to the substrate 5.

The TiN/TiC coating 1 can include a plurality of TiN-nano layers 12 and a plurality of TiC-nano layers 13. The TiN-nano layers 12 and the TiC-nano layers 13 can be alternately deposited on the Ti-bottom layer 11. Each TiN-nano layer 12 and each TiC-nano layer 13 can be adjacently arranged and bonded to form a two-layer unit. In each two-layer unit, the thickness of the TiN-nano layer 12 can range from about 10 nm to about 60 nm and the thickness of the TiC-nano layer 13 can range from about 10 nm to about 80 nm. In the illustrated embodiment, the thickness of each TiN-nano layer 12 and the thickness of each TiC-nano layer 13 can be about 50 nm. The TiN/TiC coating 1 can have 20 layers of coating each layer being made up of the TiN-nano layer 12 and the TiC-nano layer 13, total thickness can be about 1 μm. Therefore, the microhardness of the TiN/TiC coating 1 can be more than 40 GPa. In another embodiment, the Ti-bottom layer 11 can be omitted.

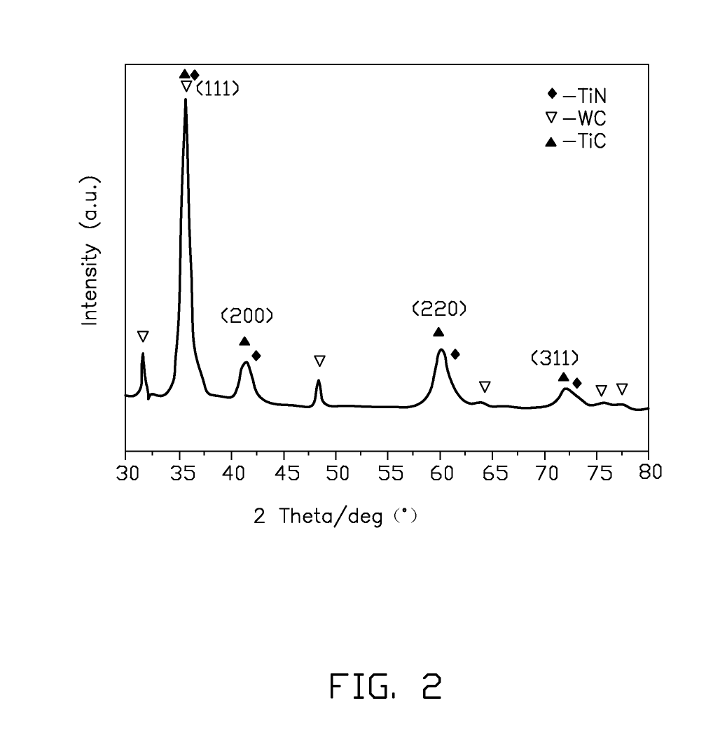

FIG. 2 illustrates that the TiN/TiC coating 1 can be formed of TiN and TiC. Lattices of each TiN-nano layer 12 and each TiC-nano layer 13 can be mismatched and cause coating inner stress when each TiN-nano layer 12 and each TiC-nano layer 13 are alternately arranged. The microhardness of the TiN/TiC coating 1 can be harder than that of the TiN layers 12 or the TiC layers 13.

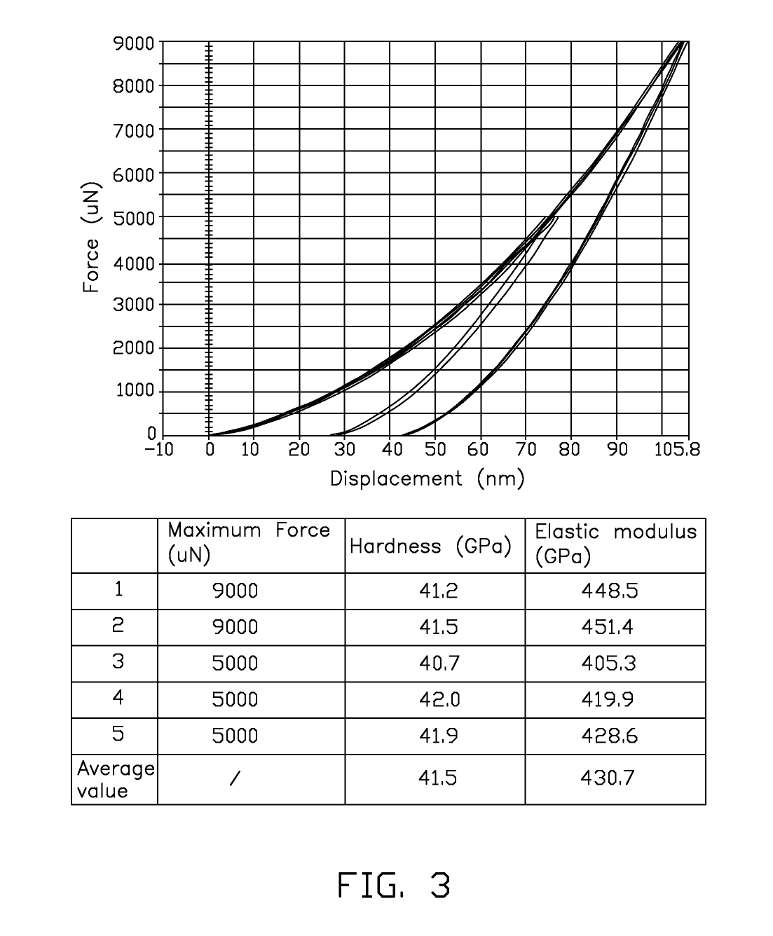

FIG. 3 illustrates that the microhardness of the TiN/TiC coating 1 can be more than 40 GPa, and the maximum microhardness of the TiN/TiC coating 1 can be about 41.5 GPa.

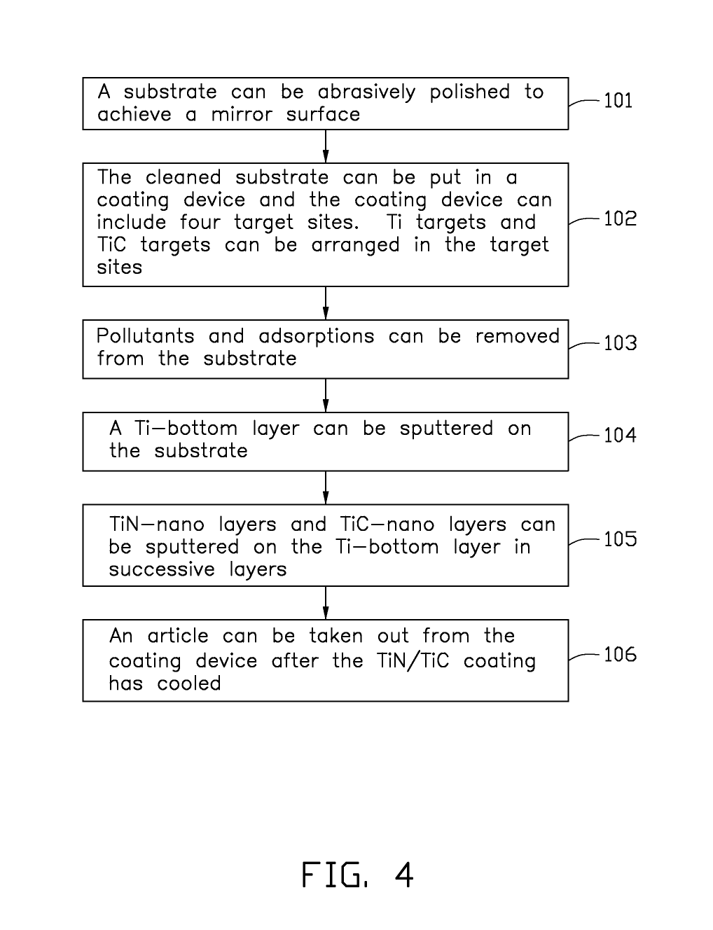

FIG. 4 illustrates a flowchart in accordance with an example embodiment. The example method is provided by way of example, as there are a variety of ways to carry out the method, such as closed field unbalanced magnetron sputter iron plating technique. The method described below can be carried out using the configurations illustrated in FIG. 1, for example, and various elements of the figure are referenced in explaining example method. Each block shown in FIG. 4 represents one or more processes, methods or subroutines, carried out in the example method. Additionally, the illustrated order of blocks is by example only and the order of the blocks can change. The example method can begin at block 101.

At block 101, a substrate 5 can be abrasively polished to achieve a mirror surface. Oil, grease and other contaminants can be removed from the substrate 5 by means of ultrasonic wave cleaning. The cleaned substrate 5 can be dried in preparation for use. The substrate 5 can be a high hardness material, such as high speed steel, cemented carbide, or cermet.

At block 102, the cleaned substrate 5 can be put in a coating device. In the illustrated embodiment, the coating device can include four target sites. Ti targets can be arranged in two target sites, and TiC targets can be arranged in the other two target sites.

At block 103, a vacuum chamber of the coating device can be evacuated to less than 4 MPa. Argon and krypton can be bubbled into the coating device to take ion etching of the substrate 5 by a biased negatively pressure. The pollutants and the adsorptions can be removed from the substrate 5.

At block 104, in order to improve adhesiveness of a TiN/TiC coating 1 attached to the substrate 5, a Ti-bottom layer 11 can be sputtered on the substrate 5. The sputtering conditions can be as follows: Ti targets can be started, a power of the Ti targets can be adjusted to 500 W-1000 W, a pressure in the coating device can be 200 MPa-500 MPa by bubbling argon and krypton flow rates of 200-300 mln/min (ml/min under 0° C. and one standard atmospheric pressure) into the coating device, a temperature of the coating device can be 400-600° C., a voltage of the ion source can be 50-100V, a biased voltage of the substrate 5 can be 50-100V, and the sputtering time can be 200-1000 seconds.

At block 105, TiN-nano layers 12 and TiC-nano layers 13 can be sputtered on the Ti-bottom layer 11 in successive layers.

The sputtering conditions of the TiN-nano layers 12 can be as follows: a power of Ti targets can be adjusted to 5000-14000 W, the krypton flow can be stopped, the pressure in the coating device can be 400 MPa-600 MPa by bubbling nitrogen flow rates of 200-300 mln/min (ml/min under 0° C. and one standard atmospheric pressure) into the coating device and adjusting the argon flow rates to 300-500 mln/min (ml/min under 0° C. and one standard atmospheric pressure), the temperature of the coating device can be 400-600° C., the voltage of the ion source can be 50-100V, the biased voltage of the substrate 5 can be 50-100V, and the sputtering time can be 100-500 s.

The sputtering conditions of the TiC-nano layers 13 can be as follows: the Ti targets can be closed and TiC targets can be started, the power of TiC targets can be adjusted to 5000-14000 W, the pressure in the coating device can be 300 MPa-500 MPa by stopping the nitrogen flow and maintaining the argon flow rates, the temperature of the coating device can be 400-600° C., the voltage of the ion source can be 50-100V, the biased voltage of the substrate 5 can be 50-100V, and the sputtering time can be 300-1000 s.

At block 106, helium can be bubbled into the vacuum chamber, and an article 100 can be taken out from the coating device after the TiN/TiC coating 1 has cooled.

The embodiments shown and described above are only examples. Many details are often found in the art such as the other features of a TiN/TiC coating. Therefore, many such details are neither shown nor described. Even though numerous characteristics and advantages of the present technology have been set forth in the foregoing description, together with details of the structure and function of the present disclosure, the disclosure is illustrative only, and changes may be made in the details, including in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A TiN/TiC coating comprising:
a plurality of TiN-nano layers; and
a plurality of TiC-nano layers;
wherein the TiN/TiC coating is a multi-layer composite coating formed by alternate deposition of TiN-nano layers and TiC-nano layers.

2. The TiN/TiC coating as claimed in claim 1, wherein the adjacent TiN-nano layer and TiC-nano layer form a two-layer unit, and the thickness of the TiN-nano layer ranges from 10 nm to 60 nm and the thickness of the TiC-nano layer ranges from 10 nm to 80 nm in each two-layer unit.

3. The TiN/TiC coating as claimed in claim 2, wherein the thickness of the TiN-nano layer and the thickness of the TiC-nano layer is 50 nm in each two-layer unit.

4. The TiN/TiC coating as claimed in claim 1, wherein the TiN/TiC coating can be total 20 layers of coating each layer being made up of the TiN-nano layer and the TiC-nano layer.

5. The TiN/TiC coating as claimed in claim 1, wherein the total thickness of the TiN/TiC coating is 1 μm.

6. The TiN/TiC coating as claimed in claim 1, wherein the microhardness of the TiN/TiC coating is more than 40 GPa.

7. A method for manufacturing a TiN/TiC coating, the method comprising:
providing a substrate in a coating device; and
forming a multi-layer composite coating by alternately sputtering a TiN-nano layer and a TiC-nano layer on the substrate;
wherein the TiN-nano layer is formed by sputtering Ti targets in the argon gas and the nitrogen gas; and the TiC-nano layer is formed by sputtering TiC targets in the argon gas.

8. The method as claimed in claim 7, wherein the sputtering conditions for forming the TiN-nano layers are as follows: a power of Ti targets is adjusted to 5000-14000 W, a nitrogen flow rate is 200-300 mln/min, an argon flow rate is 300-500 mln/min, a pressure in the coating device is 400-600 MPa, a temperature of the coating device is 400-600° C., a voltage of the ion source is 50-100V, a biased voltage of the substrate can be 50-1000V, and a sputtering time is 100-500 seconds.

9. The method as claimed in claim 7, wherein the sputtering conditions for forming the TiC-nano layers are as follows: a power of TiC targets is adjusted to 5000-14000 W, an argon flow rate is 300-500 mln/min, a pressure in the coating device is 300-500 MPa, a temperature of the coating device is 400-600° C., a voltage of the ion source is 50-100V, a biased voltage of the substrate can be 50-100V, and a sputtering time is 300-1000 seconds.

10. The method as claimed in claim 7, wherein a Ti-bottom layer is sputtered on the substrate before forming the multi-layer composite coating.

11. The method as claimed in claim 10, wherein the sputtering conditions for forming the Ti-bottom layer are as follows: a power of Ti targets is 500-1000 W, an argon flow rate and an krypton flow rate are 200-300 mln/min, a pressure in the coating device is 200-500 MPa, a temperature of the coating device is 400-600° C., a voltage of the ion source is 50-100V, and a biased voltage of the substrate can be 50-1000V, and a sputtering time is 200-1000 seconds.

12. An article comprising:
a substrate; and
a TiN/TiC coating deposited on the substrate;
wherein the TiN/TiC coating is a multi-layer composite coating formed by alternate deposition of a plurality of TiN-nano layers and a plurality of TiC-nano layers.

13. The article as claimed in claim 12, wherein a Ti-bottom layer is formed between the TiN/TiC coating and the substrate.

14. The article as claimed in claim 12, wherein the adjacent TiN-nano layer and TiC-nano layer form a two-layer unit, and the thickness of the TiN-nano layer ranges from 10 nm to 60 nm and the thickness of the TiC-nano layer ranges from 10 nm to 80 nm in each two-layer unit.

15. The article as claimed in claim 12, wherein the thickness of the TiN-nano layer and the thickness of the TiC-nano layer is 50 nm in each two-layer unit.

16. The article as claimed in claim 12, wherein the TiN/TiC coating can be total 20 layers of coating each layer being made up of the TiN-nano layer and the TiC-nano layer, and the total thickness of the TiN/TiC coating is 1 μm.

17. The article as claimed in claim 12, wherein the microhardness of the TiN/TiC coating is more than 40 GPa.
